(19) United States
(12) Patent Application Publication
(10) Pub. No.: US 2008/0220375 A1
(43) Pub. Date: Sep. 11, 2008

(54) Methods of reworking a semiconductor substrate and methods of forming a pattern in a semiconductor device

(75) Inventors: Kyoung-Chul Kim, Yongin-si (KR); Bong-Chan Kim, Seongnam-si (KR); In-Seak Hwang, Suwon-si (KR); Kwang-Wook Lee, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/074,430

(22) Filed: Mar. 4, 2008

(30) Foreign Application Priority Data
Mar. 5, 2007 (KR) 10-2007-0021478

(51) Int. Cl. G03F 7/26; G03F 7/30

(52) U.S. Cl. 430/315; 430/324

(57) ABSTRACT

In a method of reworking a substrate, an organic anti-reflection coating (ARC) layer is formed on the substrate having an amorphous carbon pattern. A photoresist pattern is formed on the organic ARC layer. The photoresist pattern is entirely exposed when the photoresist pattern has a selected level of defects, and then the photoresist pattern is removed by a developing process. The substrate may be reworked without damaging the organic ARC layer, and the amorphous carbon pattern may include an alignment key and/or an overlay key.

### CROSS-REFERENCE TO RELATED APPLICATION

This application claims priority under 35 U.S.C. §119 to Korean Patent Application No. 2007-21478 filed on Mar. 5, 2007, the contents of which are incorporated herein by reference in their entireties.

### FIELD OF THE INVENTION

Exemplary embodiments of the present invention relate to methods of reworking a semiconductor substrate and methods of forming a pattern in a semiconductor device. For example, exemplary embodiments of the present invention relate to methods of reworking a semiconductor substrate without damaging an organic anti-reflection coating (ARC) layer formed on the substrate, and methods of forming a pattern in a semiconductor device employing the methods of reworking the substrate.

### BACKGROUND

A semiconductor device sometimes requires a high storage capacity as well as high operation speed, and so certain manufacturing technologies have been developed to improve the degree of integration, reliability and response speed of the semiconductor device. For example, a process of forming fine patterns on a substrate, such as a photolithography process, for improving the degree of integration of the semiconductor device has been developed.

In the photolithography process, a photoresist pattern is utilized as an etching mask to form a fine pattern in a semiconductor device. An anti-reflection coating (ARC) layer may be formed on a layer to be etched before forming the photoresist pattern on the layer to be etched. When the ARC layer is employed before forming the photoresist pattern in the photolithography process, a fine circuit pattern may have a precise critical dimension (CD), so that process tolerances of the semiconductor manufacturing processes may increase. The ARC layer may be provided on the layer to be etched in order to reduce a light reflected from the layer to be etched while forming the photoresist pattern on the ARC layer by an exposure process.

For example, the ARC layer may prevent a standing wave effect caused by interference between incident light toward a photoresist film and reflected light from the layer to be etched. Additionally, the ARC layer may prevent or may remarkably reduce a reflection of a light caused by the topography of patterns previously formed on a substrate, and a diffused reflection of a light at edges of the patterns.

The above-mentioned ARC layer may be classified as an inorganic ARC layer or an organic ARC layer in accordance with a composition thereof. The inorganic ARC layer has good adhesion characteristics with respect to an underlying layer to be etched even when the underlying layer has a stepped portion. However, the inorganic ARC layer may not be easily removed in a subsequent process, and the adhesion strength between a photoresist film and the inorganic ARC layer may be relatively poor. Therefore, the organic ARC layer is often used instead of the inorganic ARC layer.

In a photolithography process using the organic ARC, the organic ARC layer is formed on a layer to be etched by a baking process after coating an organic ARC material on the layer to be etched by a spin coating process. After a photoresist film is formed on the organic ARC layer, an exposure process employing an exposure mask, a baking process and a developing process are sequentially performed on to the photoresist film to form a photoresist pattern on the layer to be etched.

In the photolithography process, various process parameters may affect a profile of the photoresist pattern. The profile of the photoresist pattern may have some defects caused by the various process parameters of the spin coating process, the baking process, the exposure process and the developing process. When the photoresist pattern having defects is employed in an etching process for forming a fine pattern in a semiconductor device, the fine pattern may also have defects in accordance with the photoresist pattern. Thus, when the photoresist pattern has the defects, a rework process may be performed on a semiconductor substrate having the defective photoresist pattern. In the rework process, a new photoresist pattern is formed on the semiconductor substrate after removing the defective photoresist pattern from the semiconductor substrate.

The rework process can include a dry cleaning process such as an ashing process using an oxygen (O₂) plasma, or a wet cleaning process using an organic stripper. When the photoresist pattern is removed by the ashing process using the oxygen plasma, an exposed surface of the semiconductor substrate may be damaged, so electrical characteristics of the semiconductor device provided on the substrate may deteriorate. Further, the ashing process using the oxygen plasma may undesirably remove an organic ARC layer formed beneath the photoresist pattern.

When a photoresist pattern, which is formed on a semiconductor substrate having an alignment key or an overlay key including an amorphous carbon pattern, is removed by an ashing process using an oxygen plasma, the amorphous carbon pattern may be over-etched and an organic ARC layer may also be removed. To address this problem, a silicon nitride layer serving as an etch stop layer can be formed on the alignment key or the overlay key including the amorphous carbon pattern. However, the amorphous carbon pattern may still be damaged because the silicon nitride layer has a poor step coverage on the alignment key or the overlay key.

### SUMMARY OF THE INVENTION

Exemplary embodiments of the present invention provide methods of reworking a substrate capable of removing a photoresist pattern having a selected level of defects without damage to an alignment key or an overlay key including an amorphous carbon pattern by an entire exposure process and a developing process.

Exemplary embodiments of the present invention provide methods of forming a pattern in a semiconductor device by employing the methods of reworking the substrate.

According to one aspect of the present invention, there is provided a method of reworking a substrate. In the method of reworking the substrate, an organic anti-reflection coating (ARC) layer is formed on the substrate having an amorphous carbon pattern. After forming a photoresist pattern on the organic ARC layer, the photoresist pattern is entirely exposed when the photoresist pattern has a selected level of defects. The photoresist pattern is removed by a developing process without damaging the organic ARC layer and the amorphous carbon pattern.

In exemplary embodiments, the amorphous carbon pattern may be included in an alignment key and/or an overlay key.

In exemplary embodiments, an etch stop layer may be additionally on the amorphous carbon pattern. The etch stop layer may include silicon nitride or silicon oxynitride.

In exemplary embodiments, the organic ARC layer may be formed by forming a preliminary organic ARC layer on the substrate by spin coating an organic material, and by performing a baking process on the preliminary organic ARC layer. The heating or baking process may be carried out at a temperature of about 180° C. to about 230° C.

In exemplary embodiments, the photoresist pattern may be entirely exposed to a light from a source such as an argon fluoride (ArF) laser, a krypton fluoride (KrF) laser, a fluorine (F₂) laser and/or a mercury-xenon (Hg—Xe) laser.

In exemplary embodiments, the developing process may be performed using a developing solution including a tetra-methyl ammonium hydroxide (TMAH) solution.

In exemplary embodiments, a heat treatment process may be additionally performed on the photoresist pattern after entirely exposing the photoresist pattern. The heat treatment process may be performed at a temperature of about 100° C. to about 130° C.

According to another aspect of the present invention, there is provided a method of forming a pattern in a semiconductor device. In the method of forming the pattern in the semiconductor device, a substrate having an amorphous carbon pattern and a layer to be etched is provided, and then an organic ARC layer is formed on the substrate. After a first photoresist pattern is formed on the substrate having the organic ARC layer, the first photoresist pattern is entirely exposed when the first photoresist pattern has a selected level of defects. A heat treatment process is performed on the first photoresist pattern having the selected level of defects. The first photoresist pattern having the selected level of defects is removed by a developing process without damaging the organic ARC layer. A second photoresist pattern is formed on the organic ARC layer, and then the layer to be etched is patterned using the second photoresist pattern as an etching mask.

According to exemplary embodiments, a photoresist pattern having a selected level of defects may be effectively removed from a substrate without any damage to an underlying organic ARC layer by an entire exposure process and a developing process. As a result, an alignment key and/or an overlay key having an amorphous carbon pattern positioned under the organic ARC layer may not be damaged in a removal of the defective photoresist pattern because the alignment key and/or the overlay key is not exposed to a plasma in subsequent processes. Furthermore, an additional process for forming an additional organic ARC layer on the substrate may not be required when a photoresist pattern is formed again on the substrate, so that the cost and time of semiconductor manufacturing processes may be considerably reduced.

### BRIEF DESCRIPTION OF THE DRAWINGS

The above and other features and advantages of the present invention will become more apparent by describing in detail exemplary embodiments thereof with reference to the accompanying drawings, in which:

FIG. 1 is a flow chart illustrating a method of reworking a semiconductor substrate in accordance with exemplary embodiments of the present invention; and

FIGS. 2 to 6 are cross-sectional views illustrating a method of forming patterns on the semiconductor substrate using the method of reworking a semiconductor substrate in accordance with some exemplary embodiments of the present invention.

### DESCRIPTION OF THE EMBODIMENTS

The present invention is described more fully hereinafter with reference to the accompanying drawings, in which exemplary embodiments of the present invention are illustrated. The present invention may, however, be embodied in many different forms and should not be construed as limited to the exemplary embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all in a group of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For exemplary, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to illustrations of cross sections that are schematic illustrations of idealized embodiments (and intermediate structures) of the present invention. As such, variations from the shapes of the illustrations as a result, for exemplary, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For exemplary, an implanted region illustrated as a rectangle can, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Reworking a Semiconductor Substrate

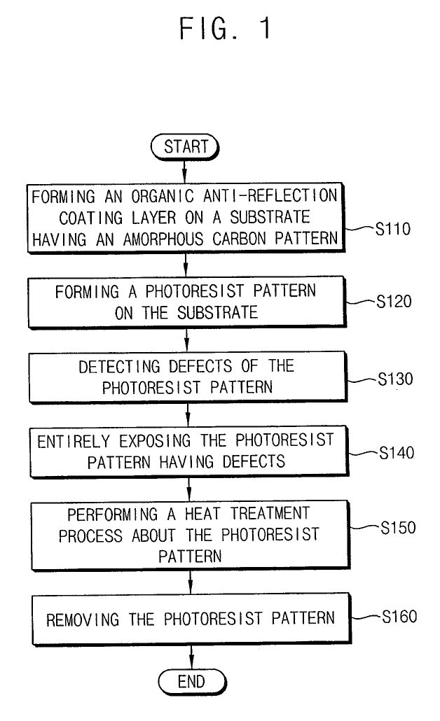

FIG. 1 is a flow chart illustrating a method of reworking a semiconductor substrate in accordance with exemplary embodiments of the present invention.

Referring to FIG. 1, an organic anti-reflection coating (ARC) layer is formed on a substrate having an amorphous carbon pattern thereon in step S110. The substrate may include a silicon substrate on which a layer to be etched is formed or a silicon-on-insulator (SOI) substrate where a layer to be etched is provided. The layer to be etched may include a polysilicon layer, a silicon nitride layer, a silicon oxide layer, a metal nitride layer, a metal layer, etc. The layer to be etched may have a single layer structure or a multi-layer structure.

In exemplary embodiments, the amorphous carbon pattern may include an alignment key and/or an overlay key. The alignment key and/or the overlay key may be employed in processes for aligning an exposure mask relative to the layer to be etched on the substrate, detecting an alignment between the exposure mask and the layer, and compensating an alignment error of the exposure mask while the layer is patterned through a photolithography process.

In exemplary embodiments, the alignment key or the overlay key may include a stepped portion formed on a scribe lane between main chips provided on a semiconductor substrate. The alignment key or the overlay key may have the structure of a trench pattern or the structure of a projecting pattern protruding from the substrate.

In some exemplary embodiments, the alignment key or the overlay key may include an amorphous carbon pattern that has an etching selectivity relative to an oxygen (O₂) plasma. The alignment key or the overlay key may additionally include an etch stop layer containing a nitride, such as silicon nitride, or an oxynitride, such as silicon oxynitride. The etch stop layer may be formed, for example, by depositing silicon nitride or silicon oxynitride on the amorphous carbon pattern through a chemical vapor deposition (CVD) process, a low pressure chemical vapor deposition (LPCVD) process, a plasma enhanced chemical vapor deposition (PECVD) process, a sputtering process, etc.

In the processes of aligning the exposure mask and compensating the alignment error of the exposure mask using the alignment key and the overlay key, an interference pattern may be generated by the stepped portion of the alignment key or the overlay key when light generated from a light source disposed in an alignment device of a stepper is irradiated onto the alignment key or the overlay key formed on the semiconductor substrate. A detecting member may detect a brightness of the interference pattern to determine a direction and/or a position of the semiconductor substrate, and then the position of the semiconductor substrate or the exposure mask may be adjusted to correctly align the mask relative to the substrate and to compensate the alignment error of the mask.

In some exemplary embodiments, the organic ARC layer may include a carbon compound such as silicon carbide (SiCx). The organic ARC layer may be formed by baking a preliminary organic ARC layer formed on the substrate at a temperature of about 180° C. to about 230° C. after the preliminary organic ARC layer is formed on the substrate using an organic material by a spin coating process.

The organic ARC layer may improve adhesion characteristics of a photoresist pattern relative to the substrate. Furthermore, the organic ARC layer may prevent a standing wave effect caused by interference between incident light into a photoresist film and reflected light from the layer to be etched. Moreover, the organic ARC layer may prevent or remarkably reduce reflection of light caused by topography of patterns previously formed on the substrate and diffused reflection of light at the edges of the patterns.

In step S120, a photoresist pattern is formed on the substrate on which the organic ARC layer is formed. The photoresist pattern may be formed on the substrate by an exposure process using light, a developing process using a developing solution, and a dry process after forming a photoresist film on the substrate.

In forming the photoresist pattern on the substrate, a surface of the substrate may be cleaned to remove contaminants remaining on the substrate having the organic ARC layer thereon. A photoresist composition may be coated on the substrate to form a preliminary photoresist film. The photoresist composition may include a meta-acrylate resin, an acrylate resin, a photo acid generator (PAG), an organic solvent, etc.

A photoresist film may be formed on the substrate by performing a first baking process on the preliminary photoresist film. The first baking process may be carried out at a temperature of about 90° C. to about 130° C. The first baking process may enhance adhesion characteristics of the photoresist film with respect to the organic ARC layer.

The photoresist film may be selectively exposed to light by an exposure process. In the exposure process, an exposure mask having a desired pattern may be aligned relative to the substrate after the exposure mask is placed on a mask stage of an exposure apparatus. The light may be irradiated onto the exposure mask so that materials in the photoresist film may react with the light passing through the exposure mask. The light employed in the exposure process may be produced by an argon fluoride (ArF) laser having a wave length of about 193 nm, a krypton fluoride (KrF) laser having a wave length of about 248 nm, a fluorine (F₂) laser, a mercury-xenon (Hg—Xe) laser, etc.

A second baking process may be performed on the substrate having the photoresist film after the exposure process. The second baking process may be performed at a temperature of about 100° C. to about 140° C. As a result of the second baking process, an exposed portion of the photoresist film may be easily dissolved in a developing solution.

The exposed portion of the photoresist film may be dissolved in a tetra-methyl ammonium hydroxide (TMAH) solution as the developing solution so that the exposed portion of the photoresist film may be removed from the substrate. The exposed portion of the photoresist film may be removed using the developing solution because an unexposed portion and the exposed portion of the photoresist film have different hydrophilic properties.

The photoresist pattern may be formed on the substrate after performing a cleaning process and a drying process on the substrate. In exemplary embodiments, the photoresist pattern may include the acrylate resin or the meta-acrylate resin in which a main chain includes single bonds of carbon and carbon. In some embodiments, the photoresist pattern may be formed on the substrate using the ArF laser.

Referring still to FIG. 1, the photoresist pattern formed on the organic ARC layer is subjected to a detection process so that defects of the photoresist pattern are detected (step S130).

In the detection process for detecting defects of the photoresist pattern formed through the exposure process, the photoresist pattern may have some defects caused by processing conditions of the exposure process and/or external processing variables. Thus, the photoresist pattern may be inspected to determine whether the photoresist pattern has defects in a regular thickness, a regular profile and/or a regular width since defects of the photoresist pattern may be caused by undesired processing conditions and/or undesired external variables in the exposure process.

When the photoresist pattern has a first or a selected level (e.g., no detectable) of defects, the layer to be etched may be suitably patterned using the photoresist pattern as an etching mask. For example, the first level or the selective level of defects may not have adverse effects on patterning the layer to be etched. When the photoresist pattern has a second or another selected (e.g., some or an unacceptable) level of defects, a rework process may be executed to recycle the substrate and the organic ARC layer by removing the photoresist pattern having the defects.

In step S140, the photoresist pattern is entirely exposed when the photoresist pattern has the second level of defects. That is, an entire exposing process is performed on the photoresist pattern having the defects.

In the entire exposure process, an entire surface of the photoresist pattern having the defects is exposed to light without using an exposure mask. The light employed in the entire exposure process may come from an argon fluoride (ArF) laser, a krypton fluoride (KrF) laser, a fluorine (F₂) laser, a mercury-xenon (Hg—Xe) laser, etc. These light sources may be used alone or in combination thereof. The entire exposure process may be executed on the photoresist pattern having the defects to induce generation of an acid (H⁺) from a photo-acid generator (PAG) included in the photoresist pattern having the defects.

In step S150, the entirely exposed photoresist pattern is thermally treated. That is, a heat treatment process is performed on the photoresist pattern after the entire exposure process.

The heat treatment process may correspond to a third baking process. In the heat treatment process, the acid generated in the entirely exposed photoresist pattern may be diffused, so the photoresist pattern may be easily dissolved in the developing solution. In other words, the entirely exposed photoresist pattern may be easily dissolved in the developing solution after the heat treatment process. In some exemplary embodiments, the heat treatment may be carried out at a temperature of about 100° C. to about 130° C., for example, at a temperature of about 110° C. to about 120° C. The heat treatment process may reduce the hardness of the photoresist pattern and may improve diffusion of the acid in the photoresist pattern.

In step S160, a second developing process is performed on the photoresist pattern that has undergone the heat treatment process, so that the defective photoresist pattern is removed from the substrate S160.

In exemplary embodiments, the second developing process may be carried out using a developing solution including a TMAH solution, so the developing may effectively dissolve the defective photoresist pattern that has been entirely exposed to light and undergone the heat treatment process. Accordingly, the defective photoresist pattern may be completely removed from the substrate by the second developing process without damaging the organic ARC layer.

In exemplary embodiments, a cleaning process and a dry process may be performed on the substrate to complete the rework process for the semiconductor substrate.

In the rework process according to embodiments of the present invention, the photoresist pattern having the defects may be efficiently removed without damaging the underlying organic ARC layer by the entire exposure process and the second developing process.

Method of Forming a Pattern in a Semiconductor Device

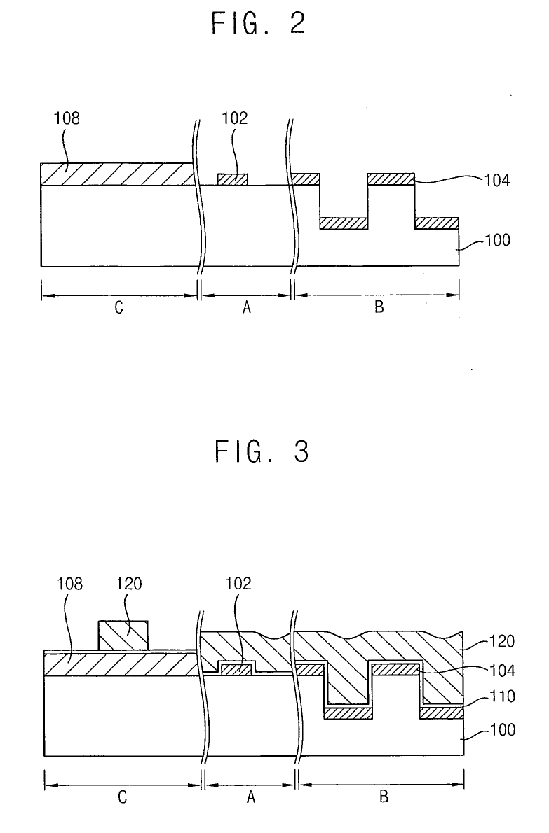

FIGS. 2 to 6 are cross-sectional views illustrating a method of forming patterns in a semiconductor device by employing the method of reworking the semiconductor substrate in accordance with exemplary embodiments of the present invention.

Referring to FIG. 2, a semiconductor substrate 100 on which an overlay key 102 and an alignment key 104 are formed is provided. The overlay key 102 may be formed in an overlay key region A of the semiconductor substrate. 100. The alignment key 104 may be positioned in an alignment key region B of the semiconductor substrate 100. Each of the overlay key 102 and the alignment key 104 includes an amorphous carbon pattern. Descriptions of the overlay key 102 and the alignment key 104 will be omitted since the overlay key 102 and the alignment key 104 have been described above.

A layer to be etched 108 is formed on the semiconductor substrate 100. The layer to be etched 108 is positioned in a cell region C of the semiconductor substrate 100 so that the overlay key region A and the alignment key region B are exposed after formation of the layer to be etched 108. The layer to be etched 108 may include a poly-silicon layer, a silicon nitride layer, a silicon oxide layer, a metal nitride layer, a metal layer, etc. The layer to be etched 108 may have a single layer structure or a multi-layer structure.

In exemplary embodiment, an etch stop layer (not illustrated) may be formed in the overlay key region A and the alignment key region B. The etch stop layer may be formed using a nitride, such as silicon nitride, or an oxynitride, such as silicon oxynitride. The etch stop layer may protect the amorphous carbon pattern by covering the amorphous carbon pattern. In some embodiments, the etch stop layer may not be provided in the overlay key 102 and/or the alignment key 104, for example, when the etch stop layer has poor step coverage.

Referring FIG. 3, an organic ARC layer 110 is formed in the overlay key region A and the alignment key region B to cover the overlay key 102 and the alignment key 104. The organic ARC layer 110 may have a uniform thickness.

The organic ARC layer 110 may be formed on the substrate 100 to improve an adhesion strength between the layer to be etched 108 and a first photoresist pattern 120 subsequently formed on the substrate 100. Furthermore, the organic ARC layer 110 may prevent a standing wave effect caused by interference between incident light irradiating onto a photoresist film and reflected light from an etching mask in an exposure process to form the first photoresist pattern 120.

In exemplary embodiments, the organic ARC layer 110 may be formed on the substrate 100 by baking a preliminary organic ARC layer (not illustrated) at a temperature of about 180° C. to about 230° C. after the preliminary organic ARC is formed on the substrate 100 by spin coating an organic material.

The first photoresist pattern 120 is formed on the organic ARC layer 110. The first photoresist pattern 120 may serve as an etching mask for etching the layer to be etched 108. In some embodiments, the first photoresist pattern 120 may have defects as a result of an exposure process and/or a developing process as described above.

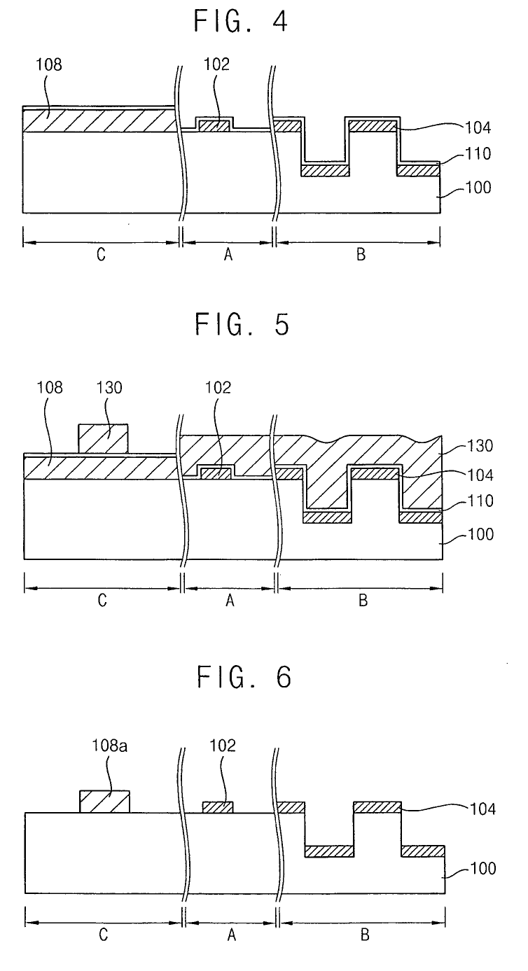

Referring to FIG. 4, a rework process for removing the first photoresist pattern 120 having the selected level of defects is performed on the substrate 100 without damage to the underlying organic ARC layer 110.

Hereinafter, the rework process for removing the defective first photoresist pattern 120 will be described in detail.

An entire surface of the defective first photoresist pattern 120 is exposed to light. That is, an entire exposure process is performed on the defective first photoresist pattern 120. In the entire exposure process, light generated from a light source may be irradiated onto the entire surface of the first photoresist pattern 120 without using an exposure mask. The light source for the entire exposure process may include an argon fluoride (ArF) laser, a krypton fluoride (KrF) laser, a fluorine (F₂) laser, a mercury-xenon (Hg—Xe) laser, etc.

A heat treatment process may be performed on the entirely exposed first photoresist pattern 120. The heat treatment process may substantially correspond to a baking process. The heat treatment process may be carried out at a temperature of about 100° C. to about 130° C., for example, at a temperature of about 110° C. to about 120° C.

The heat treatment process may reduce (e.g., minimize) the hardness of the defective first photoresist pattern 120, and also may increase (e.g., maximize) the diffusion of an acid in the defective first photoresist patter 120, so that the defective first photoresist pattern 120 may be easily dissolved by a developing solution. The defective first photoresist pattern 120 may be removed by a developing process using developing solution including a tetra-methyl ammonium hydroxide (TMAH) solution. Accordingly, the defective first photoresist pattern 120 may be completely removed from the substrate 100 by the entire exposure process and the developing process without damage to the organic ARC layer 110. The alignment key 104 and/or the overlay key 102 including the amorphous carbon pattern may also not be damaged because the organic ARC layer 110 remains on the semiconductor substrate 100.

Referring FIG. 5, a second photoresist pattern 130 is formed on the organic ARC layer 110 after the rework process. The second photoresist pattern 130 may serve as an etching mask for forming a desired pattern 108a (See FIG. 6) subsequently formed on the substrate 100 by patterning the layer to be etched 108.

Referring to FIG. 6, the organic ARC layer 110 and the layer to be etched 108 are sequentially etched using the second photoresist pattern 130 as the etching mask. The etching process may include a reactive ion etching (RIE) process, an ion beam etching (IBE) process, a plasma etching process, a laser etching process, etc. After the etching process, the organic ARC layer pattern. (not illustrated) and the desired pattern 108a are formed on the semiconductor substrate 100. For exemplary, the desired pattern 108a may include a conductive pattern and/or an insulation pattern in a semiconductor device.

The second photoresist pattern 130 and the organic ARC layer pattern are removed from the substrate 100 so that the desired pattern 108a is completed on the substrate 100. The second photoresist pattern 130 and the organic ARC layer pattern may be removed by an O₂ plasma ashing process and a cleaning process.

According to exemplary embodiments of the present invention, a photoresist pattern having a defect may be effectively removed from a substrate without any damage to an underlying organic ARC layer by an entire exposure process and a developing process. As a result, an alignment key and/or an overlay key having an amorphous carbon pattern positioned under the organic ARC layer may not be damaged in a removal of the defective photoresist pattern because the alignment key and/or the overlay key is not exposed to a plasma in subsequent processes. Furthermore, an additional process for forming an additional organic ARC layer on the substrate may not be required when a photoresist pattern is formed again on the substrate, so that the cost and time of the semiconductor manufacturing processes may be considerably reduced.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of this invention as defined in the claims. In the claims, any means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of reworking a substrate, comprising:
forming an organic anti-reflection coating (ARC) layer on the substrate having an amorphous carbon pattern;
forming a photoresist pattern on the organic ARC layer;
entirely exposing the photoresist pattern when the photoresist pattern has a selected level of defects; and
removing the photoresist pattern by a developing process without damaging the organic ARC layer and the amorphous carbon pattern.

2. The method of claim 1, wherein the amorphous carbon pattern is included in an alignment key and/or an overlay key.

3. The method of claim 1, further comprising forming an etch stop layer on the amorphous carbon pattern.

4. The method of claim 3, wherein the etch stop layer includes silicon nitride or silicon oxynitride.

5. The method of claim 1, wherein forming the organic ARC layer comprises:
forming a preliminary organic ARC layer on the substrate by spin coating an organic material; and
heating the preliminary organic ARC layer.

6. The method of claim 5, wherein heating the preliminary organic ARC layer is performed at a temperature of about 180° C. to about 230° C.

7. The method of claim 1, wherein entirely exposing the photoresist pattern is performed using a light source selected from the group consisting of an argon fluoride (ArF) laser, a krypton fluoride (KrF) laser, a fluorine (F₂) laser and a mercury-xenon (Hg—Xe) laser.

8. The method of claim 1, wherein the developing process is performed using a developing solution including a tetra-methyl ammonium hydroxide (TMAH) solution.

9. The method of claim 1, further comprising performing a heat treatment process on the photoresist pattern after entirely exposing the photoresist pattern.

10. The method of claim 9, wherein the heat treatment process is performed at a temperature of about 100° C. to about 130° C.

11. A method of forming a pattern in a semiconductor device, comprising:
providing a substrate having an amorphous carbon pattern and a layer to be etched;
forming an organic ARC layer on the substrate;
forming a first photoresist pattern on the substrate having the organic ARC layer;
entirely exposing the first photoresist pattern when the first photoresist pattern has a selected level of defects;
performing a heat treatment process on the first photoresist pattern having the selected level of defects;
removing the first photoresist pattern having the selected level of defects by a developing process without damaging the organic ARC layer;
forming a second photoresist pattern on the organic ARC layer; and
patterning the layer to be etched using the second photoresist pattern as an etching mask.

12. The method of claim 11, wherein the amorphous carbon pattern is included in an alignment key and/or an overlay key.

13. The method of claim 11, further comprising forming an etch stop layer on the amorphous carbon pattern.

14. The method of claim 11, wherein forming the organic ARC layer comprises:
forming a preliminary organic ARC layer on the substrate by spin coating an organic material; and
heating the preliminary organic ARC layer at a temperature of about 180° C. to about 230° C.

15. The method of claim 11, wherein entirely exposing the first photoresist pattern is performed using a light source selected from the group consisting of an argon fluoride laser, a krypton fluoride laser, a fluorine laser and a mercury-xenon laser.

16. The method of claim 11, wherein the developing process is performed using a developing solution including a tetra-methyl ammonium hydroxide solution.

17. The method of claim 11, wherein the heat treatment process is performed at a temperature of about 100° C. to about 130° C.
